(19) United States
(12) Patent Application Publication
(10) Pub. No.: US 2019/0109244 A1
(43) Pub. Date: Apr. 11, 2019

(54) SEMICONDUCTOR LIGHT RECEIVING ELEMENT AND METHOD FOR MANUFACTURING THE SAME

(71) Applicant: Kabushiki Kaisha Toshiba, Tokyo (JP)

(72) Inventors: Hideto FURUYAMA, Yokohama Kanagama (JP); Haruhiko Yoshida, Funabashi Chiba (JP); Kazuya Ohira, Nerima Tokyo (JP)

(73) Assignee: Kabushiki Kaisha Toshiba, Tokyo (JP)

(21) Appl. No.: 15/917,501

(22) Filed: Mar. 9, 2018

(30) Foreign Application Priority Data
Oct. 5, 2017 (JP) 2017-195266

(51) Int. Cl. H01L 31/0232; H01L 31/103; H01L 31/18

(52) U.S. Cl. CPC H01L 31/02327; H01L 31/1804; H01L 31/103

(57) ABSTRACT

According to one embodiment, a semiconductor light receiving element includes at least a first periodic structure, a semiconductor multilayered film, and a light confinement layer. The first periodic structure is provided in a light incident portion, and splits and converts, into non-perpendicular light in two or more directions, light incident from a direction perpendicular to the light incident portion. The semiconductor multilayered film includes a light absorption layer and is provided on the first periodic structure in contact with the first periodic structure. The light confinement layer is provided on the semiconductor multilayered film. A refractive index of the light confinement layer is lower than a refractive index of the semiconductor multilayered film.

### CROSS-REFERENCE TO RELATED APPLICATIONS

This application is based upon and claims the benefit of priority from Japanese Patent Application No. 2017-195266, filed on Oct. 5, 2017; the entire contents of which are incorporated herein by reference.

### FIELD

Embodiments described herein relate generally to a semiconductor light receiving element and a method for manufacturing the same.

### BACKGROUND

A semiconductor light receiving element is used in fields such as optical fiber communication, optical sensing, etc.; and Si, Ge, GaAs, GaInAs/InP, etc., are used as appropriate as the semiconductor light receiving element material according to the light receiving wavelength.

### BRIEF DESCRIPTION OF THE DRAWINGS

FIG. 1 is a schematic cross-sectional view of a semiconductor light receiving element according to a first embodiment;

FIG. 2 shows a simulation result of light propagation inside the semiconductor light emitting element according to the first embodiment;

FIG. 3 is a schematic cross-sectional view of a semiconductor light receiving element according to a second embodiment;

FIG. 4 is a schematic cross-sectional view of a semiconductor light receiving element according to a third embodiment;

FIG. 5 is a schematic cross-sectional view of a semiconductor light receiving element according to a fourth embodiment;

FIG. 6 is a schematic cross-sectional view of a semiconductor light receiving element according to a fifth embodiment;

FIG. 7 is a schematic cross-sectional view of a semiconductor light receiving element according to a sixth embodiment;

FIG. 8 is a schematic cross-sectional view of an integration example of the semiconductor light receiving element and the semiconductor laser according to the sixth embodiment;

FIG. 9A to FIG. 9C are schematic cross-sectional views showing a manufacturing process of an integration example of a semiconductor light emitting element and a semiconductor laser according to a seventh embodiment; and

FIG. 10A and FIG. 10B are schematic cross-sectional views showing the manufacturing process of an integration example of the semiconductor light emitting element and the semiconductor laser according to the seventh embodiment.

### DETAILED DESCRIPTION

According to one embodiment, a semiconductor light receiving element includes at least a first periodic structure, a semiconductor multilayered film, and a light confinement layer. The first periodic structure is provided in a light incident portion, and splits and converts, into non-perpendicular light in two or more directions, light incident from a direction perpendicular to the light incident portion. The semiconductor multilayered film includes a light absorption layer and is provided on the first periodic structure in contact with the first periodic structure. The light confinement layer is provided on the semiconductor multilayered film. A refractive index of the light confinement layer is lower than a refractive index of the semiconductor multilayered film.

According to one embodiment, the semiconductor light emitting element further includes a second periodic structure at a surface of the semiconductor multilayered film opposite to a surface contacting the first periodic structure. The second periodic structure direction-converts the non-perpendicular light into a horizontal direction.

According to another embodiment, a method for manufacturing a semiconductor light receiving element is disclosed. The method can include at least forming a first low refractive index transparent film on a silicon substrate and forming a first silicon film on the first low refractive index transparent film, forming a first periodic structure by patterning the first silicon film, forming a second low refractive index transparent film on the first periodic structure and performing planarization or causing at least protrusion heights to be uniform for a surface of the second low refractive index transparent film, forming a semiconductor multilayered film on the second low refractive index transparent film, the semiconductor multilayered film including a light absorption layer, forming a second periodic structure by patterning a surface of the semiconductor multilayered film, and forming a third low refractive index transparent film on the second periodic structure.

Various embodiments will be described hereinafter with reference to the accompanying drawings.

For convenience of description, scales of the respective figures are not always exact, and may indicate the relative positional relationship or the like. The same or similar components are marked with like reference numerals.

### First Embodiment

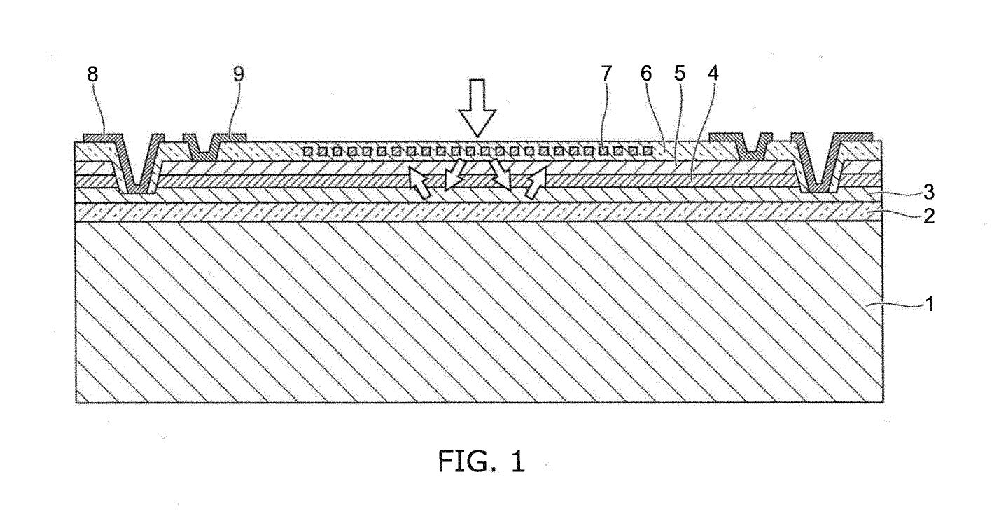

FIG. 1 is a schematic cross-sectional view of a semiconductor light receiving element showing a first embodiment. Here, an example of a surface-input semiconductor light receiving element is shown in which the light is incident from above in FIG. 1.

Semiconductor light receiving elements are used in optical fiber communication, optical sensing, etc.; and the design of the thickness of the light absorption layer is important to increase the light receiving efficiency. For example, in the case of the 1.3 μm wavelength band used in relatively short-distance optical fiber communication, the photoelectric conversion quantum efficiency of a GaInAs/InP-based surface-illuminated semiconductor light receiving element obtained for GaInAs layer (light receiving layer) thicknesses are 63% for 1 μm, 87% for 2 μm, and 95% for 3 μm. On the other hand, to provide a low-cost or high-speed semiconductor light receiving element or to integrate optical devices, there are cases where it is necessary to reduce the film thickness of the light absorption layer. However, because the photoelectric conversion efficiency of the surface-illuminated semiconductor light receiving element is dependent on the light receiving layer thickness (the optical absorption length) as described above, reducing the film thickness of the light absorption layer undesirably reduces the light receiving efficiency. To solve this problem, there is a method in which the optical absorption length is ensured by using an edge-illuminated type in which the light is incident from the side surface of the light absorption layer; but not only does the configuration of the light input portion become complex, it is also necessary to perform the optical axis alignment of the light input portion precisely; and the optical coupling degrades because it is difficult to increase the light receiving portion surface area in the case of light input using a multimode optical fiber, etc.; and as a result, the photoelectric conversion efficiency decreases.

Therefore, in the embodiment, a configuration is used in which a long optical absorption length is obtained even for a thin-film light absorption layer by causing the light to be incident from the surface of the semiconductor light receiving element and by converting the incident light into the horizontal direction in the semiconductor light receiving element interior. Specifically, an angle conversion using a diffraction grating is utilized; but a 90° conversion using a second-order diffraction grating such as that described in non-patent document 1 can convert normal incident light into horizontally-propagating light by using an extremely simple configuration; but it is difficult to increase the angle conversion efficiency and/or ensure the light-absorbing surface area.

Generally, in the case of a second-order diffraction grating having strong coupling, a relatively high 90° conversion efficiency is obtained; but the horizontally-propagating light undergoing the 90° conversion is coupled to the second-order diffraction grating, again undergoes 90° conversion, is lost by being radiated in the light incident direction and in the reverse direction; and as a result, the horizontally-propagating light decreases. Conversely, for a second-order diffraction grating having weak coupling, there are circumstances in which the proportion of the radiation loss in the light incident direction and in the reverse direction due to the light being converted into the horizontally-propagating light and again coupling with the second-order diffraction grating is low; but the angle conversion efficiency of being converted into the horizontally-propagating light by the second-order diffraction grating itself is low; therefore, as an entirety, the efficiency does not increase. In other words, in a 90° optical path conversion using a general second-order diffraction grating, there has been a trade-off between the angle conversion efficiency and the horizontal propagation loss.

Also, as discussed in non-patent document 1, for single-mode light (the light beam diameter being within about 2 times the wavelength), the conversion into the horizontally-propagating light is possible with high efficiency by using a relatively short strong coupling second-order diffraction grating; but in the case of multimode light (e.g., the luminous flux diameter being 20 times the wavelength), the horizontal propagation distance through the second-order diffraction grating lengthens; therefore, highly-efficient horizontally-propagating light conversion becomes difficult due to the trade-off between the angle conversion efficiency and the recoupling radiation loss described above. In other words, it is difficult to ensure a large light-absorbing cross-sectional area (light receiving surface area); and it is difficult to increase light receiving efficiency for multimode light and expanded light beam.

Thus, there were circumstances in which it was easy to apply a 90° optical path conversion using a second-order diffraction grating to a semiconductor laser such as in patent document 1 and patent document 2; but the application to a semiconductor light receiving element was difficult.

Thus, for a surface-illuminated semiconductor light receiving element, there are circumstances in which the light receiving efficiency decreases when the film thickness of the semiconductor light receiving layer is reduced to reduce the cost and to integrate the devices.

FIG. 1 is a schematic cross-sectional view showing an embodiment; 1 is a substrate (e.g., a semiconductor monocrystalline substrate of silicon or the like, a ceramic substrate, etc.); 2 is a light confinement layer made of a low refractive index transparent material (e.g., silicon oxide, silicon nitride, aluminum oxide, etc.); 3 is a semiconductor layer (e.g., silicon, InP, GaAlAs, GaN, SiC, etc.); 4 is a light absorption layer (e.g., SiGe, GaInAs, GaAs, InGaN, etc.); 5 is a semiconductor layer (e.g., silicon, InP, GaAlAs, GaN, SiC, etc.); 6 is a low refractive index transparent material (e.g., silicon oxide, silicon nitride, aluminum oxide, etc.); 7 is a high refractive index transparent material (e.g., monocrystalline silicon, polycrystalline silicon, amorphous silicon, SiC, GaN, etc.); 8 is an electrode of the semiconductor layer 3; 9 is an electrode of the semiconductor layer 5; and, for example, the semiconductor layer 3 and the semiconductor layer 5 form a p-n junction as an n-type and p-type pair or as a p-type and n-type pair and make it possible to apply an electric field for extracting the light-absorbing carriers generated by the light absorption layer 4. Or, for example, the entire semiconductor layer 3 and semiconductor layer 5 may be unified and may be of the n-type or the p-type with a low concentration; on one of the semiconductor layer surfaces, a two-system Schottky electrode or MIS (Metal Insulator Semiconductor) electrode having a comb teeth configuration may be formed so that the comb teeth mesh to oppose each other; and the electric field may be applied from the semiconductor layer surface.

The reflections at the interface between the low refractive index transparent material 6 and the semiconductor layer 5 can be suppressed by setting the low refractive index transparent material 6 between the high refractive index transparent material 7 and the semiconductor layer 5 to be sufficiently thinner than the light receiving wavelength, e.g., not more than ⅕ of the light receiving wavelength. An anti-reflection film may be provided at the interface between the low refractive index transparent material 6 and the semiconductor layer 5 in the case where it is necessary to set the thickness of the low refractive index transparent material 6 between the high refractive index transparent material 7 and the semiconductor layer 5 to be relatively thick. For example, a λ/4 film (λ being the in-medium wavelength) of a material having a refractive index near the square root of the product of the refractive indexes of the two materials is provided; and in the case of the light reception of the wavelength of 1.3 μm described above, for example, it is sufficient to provide 0.16 μm of SiN having a refractive index of 2.

It is sufficient to determine the combination of the materials of the high refractive index transparent material, the semiconductor layer, and the light absorption layer according to the light receiving wavelength. For example, in the case where light of a wavelength of 1.3 μm is received, 1 is set to Si; 2 is set to SiO₂ (e.g., having a thickness of 0.5 μm); 3 is set to InP (e.g., having a thickness of 0.3 μm); 4 is set to GaInAs (e.g., having a thickness of 0.5 μm); 5 is set to InP (e.g., having a thickness of 0.5)μm); 6 is set to SiO₂; and 7 is set to Si (e.g., having a thickness of 0.4 μm). For example, the SiO₂ of 6 is set to a thickness of 0.15 μm between the InP of 5 and the Si of 7, and is set to a thickness of 0.4 μm on the Si of 7.

As shown in the drawing, the high refractive index transparent material of 7 is configured to have a periodic arrangement, and is set to annihilate the zeroth-order diffracted light (the light traveling in a straight line) of the light perpendicularly incident from the surface. As a condition of the annihilation, the thickness is set to provide a phase difference (an optical path length difference λ/2) of π for the light passing through the high refractive index transparent material 7 and the light passing between the high refractive index transparent materials 7 (through the low refractive index transparent material 6). In other words, a thickness t₇ of the high refractive index transparent material 7 is set to t₇=λ₀/(2(n₇ₑ−n₆ₑ)) (λ₀ being the vacuum wavelength), where n₇ₑ, is the equivalent refractive index sensed by the light passing through the high refractive index transparent material 7, and n₆ₑ is the equivalent refractive index sensed by the light passing through the low refractive index transparent material 6 between the high refractive index transparent materials 7.

By such a setting, the instant that the light incident perpendicularly from above in FIG. 1 passes through the periodic structure of the high refractive index transparent material 7, the light passing through the high refractive index transparent material 7 and the light passing between the high refractive index transparent materials 7 cancel each other; and the zeroth-order light (the light traveling in a straight line) of the diffraction grating made of the high refractive index transparent material 7 is annihilated. As a result, the light becomes only the higher order diffracted light of the diffraction grating made of the high refractive index transparent material 7 (hereinbelow, called the incidence diffraction grating); the light is split into±first-order and higher order diffracted light by the incidence diffraction grating; and angle conversion is performed. At this time, a diffraction angle θ₆ inside the low refractive index transparent material 6 of the first-order diffracted light passing through the incidence diffraction grating is θ₆=sin⁻¹(λ₀/n₆∧₇); the first-order diffracted light refracts when entering the semiconductor layer 5; therefore, a refraction angle θ₅ inside the semiconductor layer 5 is θ₅=sin⁻¹((n₆/n₅)sin θ₆)=sin⁻¹(λ₀/n₅∧₇). n₆ is the refractive index of the low refractive index transparent material 6; ∧₇ is the period of the diffraction grating made of the high refractive index transparent material 7; and n₅ is the refractive index of the semiconductor layer 5.

Accordingly, in the embodiment of FIG. 1, the light that is incident perpendicularly from the surface is converted into higher order light (mainly first-order light) by the incidence diffraction grating and propagates in oblique directions; therefore, the light is not radiated and scattered in the incident direction, etc., by recoupling as-is with the incidence diffraction grating; and the light propagates obliquely through the semiconductor layer 5, the light absorption layer 4, and the semiconductor layer 3 and reaches the low refractive index transparent material 2.

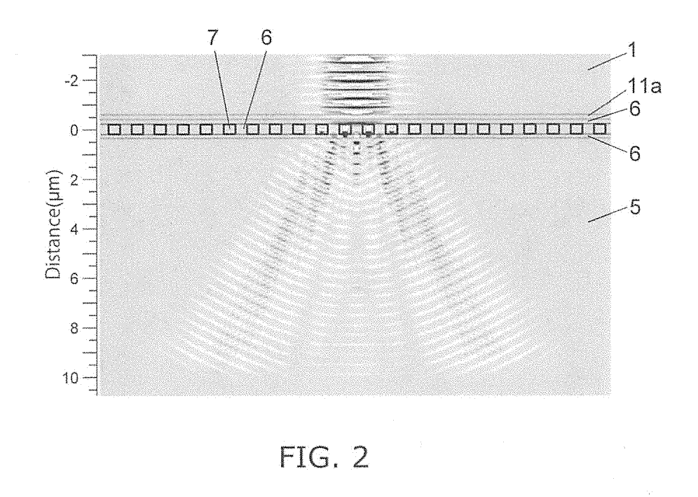

FIG. 2 shows an example of a simulation of this description. In FIG. 2, the light is perpendicularly incident from the upper portion; and the silicon substrate 1 is used as the light incident surface to inclusively show an embodiment described below. In FIG. 2, 11a is an anti-reflection film that prevents the reflections at the interface of the low refractive index transparent material (e.g., SiO₂) of 6; and, for example, 0.16 μm of SiN having a refractive index of 2 is provided. In the description of the embodiment of FIG. 1, the result is the same even if the entire silicon substrate 1 and the entire anti-reflection film 11a are replaced with the low refractive index transparent material 6.

In FIG. 2, 5 is set to InP; 6 is set to SiO₂; 7 is set to Si (having a thickness of 0.4 μm); 0.15 μm is provided between the InP of 5 and the Si of 7; and 0.4 μm is provided between the Si of 7 and the SiN of 11a. The Si of 7 is set to have a width of 425 nm and a spacing of 425 nm (∧₇=850 nm). The electric field amplitude was mapped by setting the incident light wavelength to 1.3 μm. In this configuration, calculating θ₅ using the formula described above gives about 28°, which substantially matches the result of FIG. 2. Although a slight component transmitted perpendicularly is seen in FIG. 2, this is due to a slight shift from the ideal zeroth-order light annihilation conditions; and it can be seen that almost all of the light is converted into first-order diffracted light.

Although the simulation results of FIG. 2 show the case where the light incident on the incidence diffraction grating is a TE wave (S-polarized light), a similar effect is obtained for a TM wave (P-polarized light) as well; therefore, it is desirable for the incidence diffraction grating to be not a one-dimensional grating but a two-dimensional grating. In other words, instead of a one-dimensional grating in which comb teeth are arranged in a designated direction, it is desirable to use a two-dimensional grating having a square grating in which the comb teeth cross longitudinally and laterally in the light incident surface. Thereby, any polarized wave of the light that is perpendicularly incident can be converted into the first-order diffracted light recited above for all of the polarized waves by the orthogonal polarized waves being split and diffracted by the longitudinal grating and the lateral grating. Also, for example, not only an orthogonal square grating but also a triangular grating or a hexagonal grating may be used as the two-dimensional diffraction grating.

The incident light that propagates obliquely through the semiconductor layer 5, the light absorption layer 4, and the semiconductor layer 3 and reaches the low refractive index transparent material 2 passes through the light absorption layer 4 obliquely partway through and undergoes light absorption. In the case where 1.3 μm light is perpendicularly incident on the GaInAs of the light absorption layer (0.5 μm thick) described above, the light receiving efficiency is about 39%; but in the case where the light passes through obliquely as in the embodiment, the optical absorption length lengthens; and in the case of the configuration example of FIG. 2, the light receiving efficiency is 43%. Here, the incident light that is not absorbed is incident obliquely on the interface between the semiconductor layer 3 and the low refractive index transparent material 2, but is reflected due to the refractive index difference between the semiconductor layer 3 and the low refractive index transparent material 2. As described above, the light that arrives obliquely is S-polarized light; and the reflectance increases as the incident angle increases. In particular, all of the light at a total internal reflection angle θₘ or greater is reflected. A total internal reflection angle θₘ₃₂ of the light traveling from the semiconductor layer 3 side to the low refractive index transparent material 2 side is θₘ₃₂=sin⁻¹(n₃/n₂), where n₃ is the refractive index of the semiconductor layer 3, and n₂ is the refractive index of the low refractive index transparent material 2; and θₘ₃₂ is about 28° when the semiconductor layer 3 is set to InP (having a refractive index of 3.2) and the low refractive index transparent material 2 is set to SiO₂ (having a refractive index of 1.5).

In other words, in the configuration example of the embodiment, θₘ₃₂ substantially matches θ₅ described above; and the incident light that propagates obliquely through the semiconductor layer 5, the light absorption layer 4, and the semiconductor layer 3 and reaches the low refractive index transparent material 2 undergoes total internal reflection at the interface between the semiconductor layer 3 and the low refractive index transparent material 2. Accordingly, in the embodiment, the incident light again passes through the light absorption layer 4; and the absorption length is not less than 2 times that of perpendicular incidence. Further, with the effect of the oblique transmission, the absorption length is 2.26 times in the configuration example of FIG. 2. As a result, the light receiving efficiency is 68% or more; and it can be seen that a high light receiving efficiency is obtained even in the case where the light absorption layer thickness is set to be 0.5 μm and is thin.

Thereby, it is possible to reduce the costs such as the material cost of the semiconductor multilayered film, the processing cost, etc., by reducing the light absorption layer thickness; and a high-speed response also is possible because the travel time of the light absorption carriers also can be reduced. Further, the integration with other semiconductor elements, etc., also is easy; and a highly functional semiconductor light receiving element such as an optical integrated device or the like also is possible.

### Second Embodiment

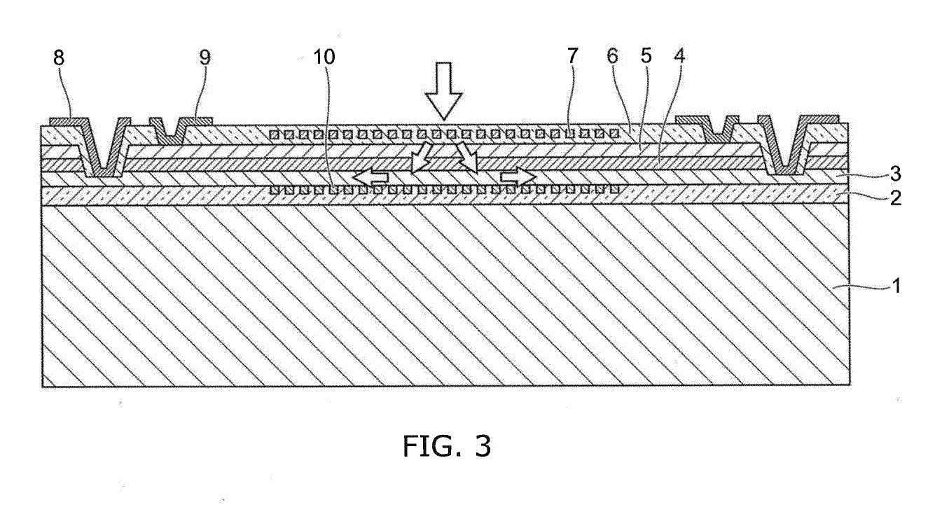

FIG. 3 is a schematic cross-sectional view of a semiconductor light receiving element showing a second embodiment. Here, an example of a surface-input semiconductor light receiving element in which the light is incident from above in FIG. 3 is shown.

In FIG. 3, 10 is a high refractive index transparent material (e.g., monocrystalline silicon, polycrystalline silicon, amorphous silicon, SiC, GaN, InP, GaAlAs, etc.) and is formed in contact with the semiconductor layer 3. Other than the high refractive index transparent material 10 in FIG. 3, the configuration is equivalent to that of the first embodiment of FIG. 1; and a detailed description is therefore omitted.

As shown in the drawing, the high refractive index transparent material 10 is configured to have a periodical arrangement; and the period is set so that the incident light is angle-converted to the horizontal direction. The condition of the diffraction grating made of the high refractive index transparent material 10 (hereinbelow, called the horizontal diffraction grating) diffracting, to the horizontal direction, the light angle-converted to θ₅ by the incidence diffraction grating of 7 is ∧₁₀=λ₀/(n₁₀ₑ−n₃ sin θ₃). Here, n₃ is the refractive index of the semiconductor layer 3; n₁₀ₑ is the equivalent refractive index sensed by the light propagating in the horizontal direction; ∧₁₀ is the period of the horizontal diffraction grating made of the high refractive index transparent material 10; θ₃ is the incident angle from the semiconductor layer 3; and θ₃=θ₅ because there is particularly no angle conversion partway.

In the embodiment of FIG. 1, the absorption length is enlarged to be not less than 2 times the light absorption layer thickness by utilizing the total internal reflection of the interface between the semiconductor layer 3 and the low refractive index transparent material 2; but here, the remaining light that did not undergo light absorption is scattered by the incidence diffraction grating; therefore, there is a limit to the increase of the light receiving efficiency. Conversely, in the second embodiment shown in FIG. 3, the light that reaches the low refractive index transparent material 2 is not simply reflected, but undergoes angle conversion in the horizontal direction due to the high refractive index transparent material 10 and is absorbed by the light absorption layer 4 while propagating in the horizontal direction. Therefore, an extremely large absorption length is obtained; and a light receiving efficiency that is higher than that of the first embodiment is obtained easily.

Here, because the incidence diffraction grating made of the high refractive index transparent material 7 performs the diffraction using a thin diffraction grating, it is desirable to use a so-called HCG (High-index-Contrast subwavelength Grating); and the high refractive index transparent material 7 is completely buried inside the low refractive index transparent material 6. In such a case, the refractive indexes of the high refractive index transparent material (Si) and the low refractive index transparent material (SiO₂) described above are about 3.5 and 1.5 respectively for a wavelength of 1.3 μm; and the refractive index difference is a maximum of 2 and is large. Actually, the refractive index difference is smaller because of the function as a structural equivalent refractive index; but even so, for the combination of the materials recited above, a refractive index difference of 1 or more is obtained easily; and the diffraction grating has extremely high contrast.

On the other hand, the horizontal diffraction grating made of the high refractive index transparent material 10 diffracts the incident light in the horizontal direction and causes light propagation through the diffraction grating region; therefore, there are circumstances in which a HCG would have a large radiation loss; and the horizontal propagation length could not be long. Therefore, here, a configuration is used in which the semiconductor layer 3 that has a high refractive index (e.g., InP having a refractive index of 3.2) and the high refractive index transparent material 10 (e.g., Si having a refractive index of 3.5) contact each other; and a configuration is used in which the equivalent refractive index difference between the high refractive index region and the low refractive index region is small. In other words, the configuration is such that the low refractive index region equivalent refractive index is determined by the average refractive index of the semiconductor layer 3 and the low refractive index transparent material 2 (e.g., SiO₂ having a refractive index of 1.5); and the contrast of the horizontal diffraction grating can be adjusted by adjusting the thickness of the high refractive index transparent material 10. Therefore, the horizontal-direction light propagation loss in the horizontal diffraction grating region can be adjusted; the horizontal propagation length can be set to be longer; and the light receiving efficiency can be increased.

There is a risk that the diffraction efficiency to the horizontal direction may decrease by reducing the contrast of the horizontal diffraction grating made of the high refractive index transparent material 10; but because the incident light is S-polarized light, as described in the first embodiment, the refractive. index difference between the semiconductor layer 3 and the low refractive index transparent material 2 and the interface reflection due to the deflection (the angle conversion) of the incidence diffraction grating exist; the light that passes through the horizontal diffraction grating is low; and the efficiency decrease is not large. As a result, due to the angle conversion using the horizontal diffraction grating and the reflections at the interface between the semiconductor layer 3 and the low refractive index transparent material 2, the incident light optically couples with an optical waveguide made from the light absorption layer 4 as a core, the semiconductor layers 3 and 5 as intermediate cladding, and the low refractive index transparent materials 2 and 6 as outer cladding; and because the light beam gradually enlarges beyond the scattering conditions of the horizontal diffraction grating and the incidence diffraction grating, the radiation loss due to the horizontal diffraction grating and the incidence diffraction grating also is suppressible.

As an example of an element configuration, 1 is set to a Si substrate; 2 is set to SiO₂ (e.g., having a thickness of 0.5 μm); 3 is set to InP (e.g., having a thickness of 0.3 μm); 4 is set to GaInAs (e.g., having a thickness of 0.2 μm); 5 is set to InP (e.g., having a thickness of 0.5 μm); 6 is set to SiO₂ (e.g., having a thickness of 0.95 μm, but having a thickness of 0.15 μm between the InP of 5 and the Si of 7 and a thickness of 0.4 μm on the Si of 7); 7 is set to Si (e.g., having a thickness of 0.4 μm, a width of 425 nm, and a spacing of 425 nm (∧₇=850 nm)); 10 is set to Si (e.g., having a thickness of 0.1 μm, a width of 725 nm, and a spacing of 725 nm (∧₁₀=1450 nm)); the light receiving wavelength is set to 1.3 μm; and in such a case, the light receiving efficiency that is obtained is 80% or more even though the light absorption layer is thinner than that of the first embodiment. This shows that the light absorption path is different from that of the first embodiment in which the light absorption is dominated by the optical path length passing through the light absorption layer 4 perpendicularly or obliquely.

### Third Embodiment

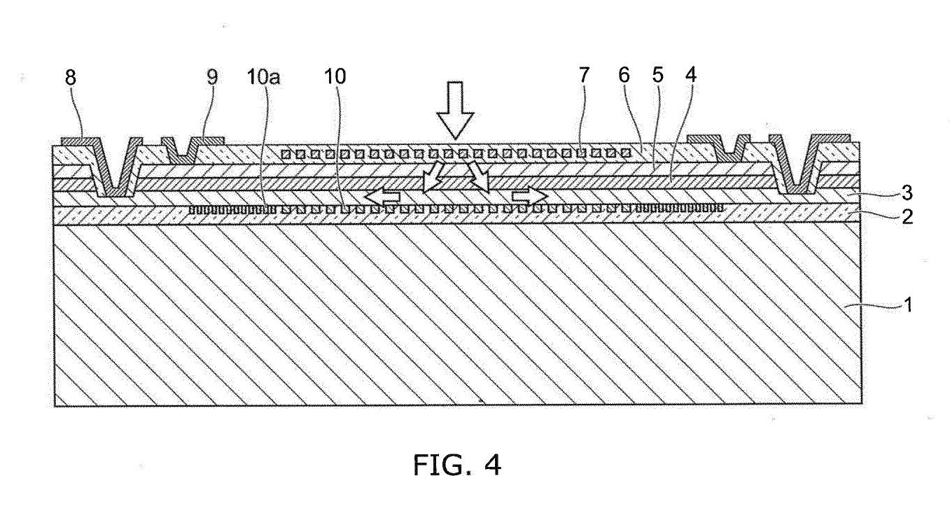

FIG. 4 is a schematic cross-sectional view of a semiconductor light receiving element showing a third embodiment. Here, an example of a surface-input semiconductor light receiving element in which the light is incident from above in FIG. 4 is shown.

In FIG. 4, 10a is a high refractive index transparent material (e.g., monocrystalline silicon, polycrystalline silicon, amorphous silicon, SiC, GaN, InP, GaAlAs, etc.), and is formed in contact with the semiconductor layer 3. Other than the high refractive index transparent material 10a in FIG. 4, the configuration is equivalent to that of the second embodiment of FIG. 3; and a detailed description is therefore omitted.

The high refractive index transparent material 10a is configured to have a periodical arrangement as shown in the drawing; and the period is set to horizontally reflect the light that is angle-converted into the horizontal direction by the high refractive index transparent material 10, horizontally propagates, and propagates past the high refractive index transparent material 10 region (the horizontal diffraction grating region), that is, the light that leaks in the horizontal direction. For this setting, it is sufficient to satisfy the so-called Bragg reflection condition; and it is sufficient for ∧₁₀ₐ=mλ₀/2n₁₀ₑ. Here, m=1, 3, 5, . . . , n₁₀ₑ is the equivalent refractive index sensed by the light propagating in the horizontal direction; and ∧₁₀ₐ is the period of the diffraction grating made of the high refractive index transparent material 10a. For example, in the case where the equivalent refractive index n₁₀ₑ is 2.4, it is sufficient to set ∧₁₀ₐ to periods of 270 nm and 813 nm.

Thereby, the leaking to the outside is suppressible particularly for the light that propagates in the horizontal direction due to the horizontal diffraction grating made of the high refractive index transparent material 10 and is converted into the horizontally-propagating light at the end portion vicinity of the horizontal diffraction grating; and an increase of the light receiving efficiency is possible. Also, because the sensitivity is made uniform in the light receiving surface, an effect is realized also for modal noise suppression in the case where multimode light such as multimode optical fiber or the like is received.

Although the description of the Bragg reflector 10a is omitted from the description of subsequent embodiments to simplify the description, it goes without saying that the Bragg reflector 10a may be appropriately applied.

### Fourth Embodiment

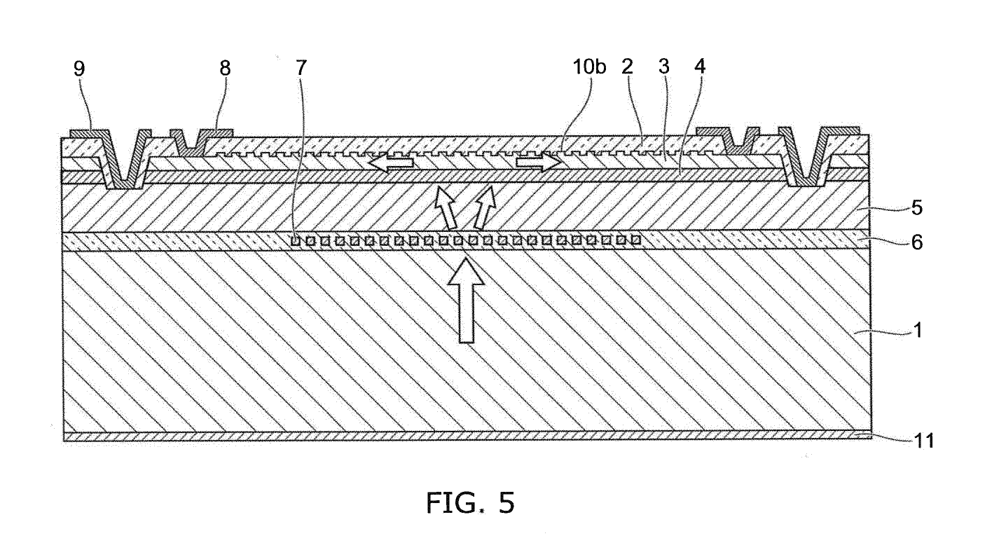

FIG. 5 is a schematic cross-sectional view of a semiconductor light receiving element showing a fourth embodiment. Here, an example of a surface-input semiconductor light receiving element in which the light is incident from below in FIG. 5 is shown.

In FIG. 5, 10b is a high refractive index transparent material formed by partially patterning the surface of the semiconductor layer 3, has a periodical arrangement as shown in the drawing, and has a period set so that the incident light is angle-converted into the horizontal direction. 11 is an anti-reflection film that suppresses reflections due to the refractive index difference between the substrate 1 and air. For example, in the case where the substrate 1 is set to Si, it is sufficient to provide 0.17 μm of SiN adjusted to have a refractive index of 1.9. Other than the substrate 1, the high refractive index transparent material 10b, and the anti-reflection film 11 in FIG. 5, the configuration is the vertically inverted configuration of the second embodiment of FIG. 3; and a detailed description is omitted.

The condition of the diffraction grating made of the high refractive index transparent material 10b (hereinbelow, called the horizontal diffraction grating) diffracting, to the horizontal direction, the light angle-converted to θ₅ by the incidence diffraction grating of 7 is ∧_{10b}=λ₀/(n₁₀ₑ−n₃ sin θ₃). Here, n₃ is the refractive index of the semiconductor layer 3; n₁₀ₑ is the equivalent refractive index sensed by the light propagating in the horizontal direction; ∧_{10b} is the period of the horizontal diffraction grating made of the high refractive index transparent material 10b; θ₃ is the incident angle from the semiconductor layer 3; and θ₃=θ₅ because angle conversion does not particularly occur partway.

As an element configuration example, 1 is set to a Si substrate; 6 is set to SiO₂ (e.g., having a thickness of 0.95 μm, but having a thickness of 0.4 μm between the Si substrate of 1 and the Si of 7, and a thickness of 0.15 μm between the Si of 7 and the InP of 5); 7 is set to Si (e.g., having a thickness of 0.4 μm, a width of 425 nm, and a spacing of 425 nm (∧₇=850 nm)); 5 is set to InP (e.g., having a thickness of 0.8 μm); 4 is set to GaInAs (e.g., having a thickness of 0.2 μm); 3 is set to InP (e.g., having a thickness of 0.3 μm); 10b is the surface patterning of the InP of 3 (e.g., having a depth of 0.1 μm, a width of 725 nm, and a spacing of 725 nm (∧_{10b}=1450 nm)); and 2 is set to SiO₂ (e.g., having a thickness of 0.5 μm).

In FIG. 5, it is desirable for 7 to be a HCG; and the spacing between the Si substrate 1 and the Si 7 of the SiO₂ 6 is set to 0.4 μm. In such a case, it is desirable to provide an anti-reflection film (not illustrated) between the Si substrate 1 and the SiO₂ 6 because reflections occur at the interface between the Si substrate 1 and the SiO₂ 6. For example, 0.16 μm of SiN having a refractive index of 2 is provided as the anti-reflection film. For this configuration, the light receiving efficiency that is obtained in the case where the light receiving wavelength is set to 1.3 μm is 80% or more even though the light absorption layer is thin.

In the case of the embodiment of FIG. 5, for 10b, it is unnecessary to separately form the high refractive index transparent material 10 as in FIG. 3; and it is sufficient to pattern the semiconductor layer 3 from the surface. Therefore, the materials and the number of processing steps for forming 10 as in FIG. 3 can be reduced; and because the semiconductor layer 3 and the high refractive index transparent material 10b are continuous, there is also an effect that the optical coupling loss between the semiconductor layer 3 and the horizontal diffraction grating is low.

Also, in the case of the embodiment of FIG. 3, the thickness of the semiconductor layer of 3 determines the coupling distance between the horizontal diffraction grating and the light absorption layer; and in the case where the semiconductor layer of 3 is too thick, the optical coupling between the horizontal diffraction grating and the light absorption layer 4 decreases; and the light receiving efficiency decreases. Therefore, it is necessary to form the semiconductor layer 3 to be thin; the layer resistance easily becomes large; and the via patterning margin (the etching margin) for forming the electrode 8 is small. Conversely, in the embodiment of FIG. 5, the semiconductor layer 5 on the lower side is not between the horizontal conversion diffraction grating and the light absorption layer 4 and has little effect on the light receiving efficiency even if formed to be relatively thick. Therefore, there are advantages in that the layer resistance can be reduced by forming the semiconductor layer 5 to be relatively thick; and the via patterning margin for forming the electrode 9 can be large. As a result, in the embodiment of FIG. 5, a cost reduction is possible due to the process reduction of the element patterning and the increase of the yield.

### Fifth Embodiment

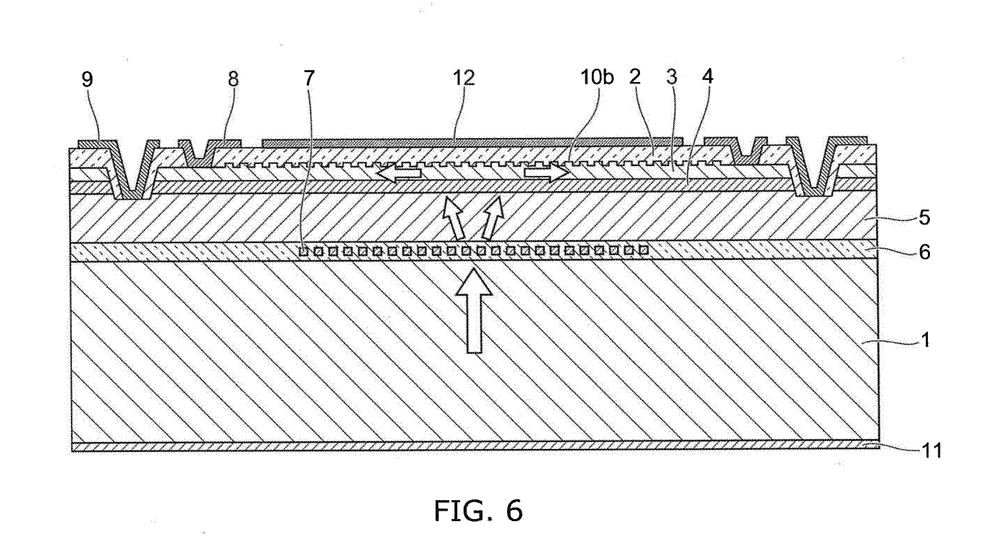

FIG. 6 is a schematic cross-sectional view of a semiconductor light receiving element showing a fifth embodiment. Here, an example of a surface-input semiconductor light receiving element in which the light is incident from below in FIG. 6 is shown.

In FIG. 6, 12 is a reflective film provided on the surface of the low refractive index transparent material 2. Other than the reflective film 12 in FIG. 6, FIG. 6 is similar to the fourth embodiment of FIG. 5; and a detailed description is omitted.

As the reflective film 12, a metal such as Al, Ag, Au, Pt, Ni, or the like, a dielectric mutlilayer reflective film, etc., can be used. Although the incidence diffraction grating made of the high refractive index transparent material 10b annihilates the zeroth-order diffracted light (the light traveling in a straight line), a portion of leakage light may occur according to the wavelength, the incident angle, the error of the element patterning, etc., as shown in FIG. 2. Although the light that travels in a straight line and leaks at the incidence diffraction grating is absorbed by the light absorption layer 4, the light undesirably scatters to the outside easily from the surface of the low refractive index transparent material 2 and becomes a simple loss. Therefore, by providing the reflective film 12 on the surface of the low refractive index transparent material 2, the leakage light is reflected; and the light absorption in the light absorption layer 4 is promoted. Therefore, the fifth embodiment of FIG. 6 can realize the highest light receiving efficiency by combining the Bragg reflector 10a (not illustrated) formed on the outer side of the high refractive index transparent material 10b simultaneously with lob. Also, the reflective film 12 has the effect of shielding stray light from outside the semiconductor light receiving element and reduces element noise and misoperations.

### Sixth Embodiment

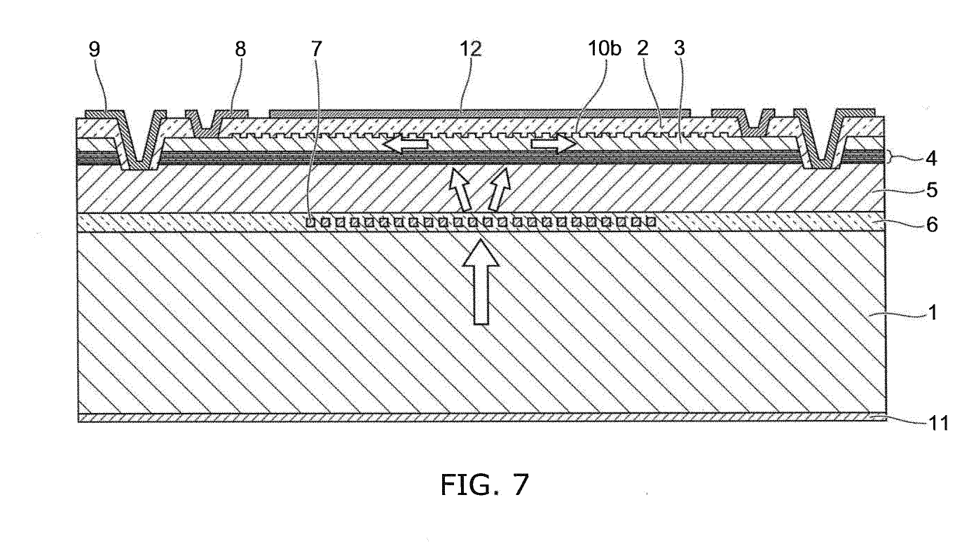

FIG. 7 is a schematic cross-sectional view of a semiconductor light receiving element showing a sixth embodiment. Here, an example of a surface-input semiconductor light receiving element in which the light is incident from below in FIG. 7 is shown.

In FIG. 7, 4 is a multi-quantum well (MQW) light absorption layer and is formed by, for example, stacking several periods of a structure in which a well layer of GaInAsP or AlGaInAs (e.g., having a thickness of 6 nm) is sandwiched between barrier layers of InP or AlGaInAs having a wide bandgap (e.g., having a thickness of 10 nm). The bandgap and the crystal grating constant can be changed by adjusting the composition for GaInAsP and AlGaInAs; and the MQW quantum level (a bandgap wavelength λ_{g}) can be determined by the combination of the bandgap and the crystal grating constant and by the quantum well thickness.

The embodiments up to FIG. 6 show that a high light receiving efficiency is realizable using an extremely thin light absorption layer; and a high light receiving efficiency can be realized also for an extremely thin light absorption layer such as a MQW. For example, in a MQW using ten layers of the well layer having the thickness described above, the absorption length of the light absorption layer 4 is merely 60 nm in the perpendicular direction; and the light receiving efficiency is about 6% and is extremely low. However, according to the sixth embodiment of FIG. 7, by perpendicularly patterning the via side surface on the light receiving portion side of the electrode 9 or the not-illustrated Bragg reflector 10a, the leakage light in the horizontal direction can be confined; an optical absorption length of several 100 μm is ensured; and a light receiving efficiency of 90% or more can be realized.

Therefore, in the sixth embodiment of FIG. 7, a bandgap shift can be performed by utilizing the QCSE (Quantum Confined Stark Effect) due to applying an electric field to the MQW; and operation switching can be performed between light reception (λ_{g}>λᵢₙ) and non-light reception (λ_{g}<λᵢₙ) for a wavelength (λᵢₙ) near the bandgap edge. In other words, a light receiving switch element that could not be realized by a conventional surface-input semiconductor light receiving element is realizable. Also, it is possible for the same MQW layer to function as a light-emitting layer by current injection; and a light-emitting element and a light receiving element can be integrated by collectively forming from one MQW layer.

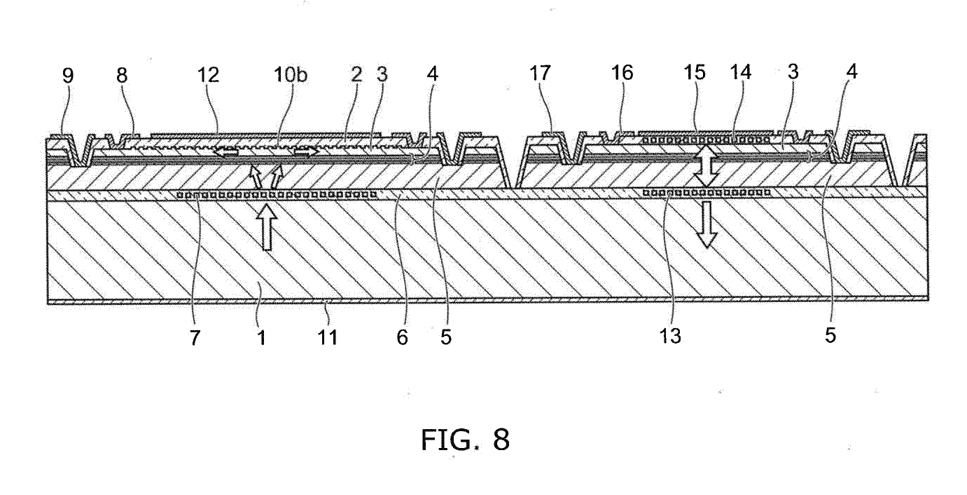

FIG. 8 is a schematic cross-sectional view of an integration example of a semiconductor light receiving element and a semiconductor laser showing a modification of the sixth embodiment. Here, an integration example is shown of a surface-input semiconductor light receiving element (left) in which the light is incident from below in FIG. 8 and a surface-type semiconductor laser (right) that outputs light downward in FIG. 8.

In FIG. 8, for example, 1 is set to a Si substrate; 7 is set to Si (e.g., having a thickness of 0.4 μm, a width of 425 nm, and a spacing of 425 nm (∧₇=850 nm)); 13 and 14 are set to Si (e.g., having a thickness of 0.4 μm, a width of 275 nm, and a spacing of 275 nm (∧₁₃=∧₁₄=550 nm)); 5 is set to n-InP (e.g., having a thickness of 0.8 μm); 4 is set to a MQW an AlGaInAs well layer of 6 nm having a narrow bandgap, an AlGaInAs barrier layer of 10 nm having a wide bandgap, the number of wells being 10, having a light emission wavelength of 1.3 μm); 3 is set to p-InP (e.g., having a thickness of 0.3 μm); 6 is set to SiO₂ (e.g., having a thickness of 0.95 μm, but having 0.4 μm between the Si substrate of 1 and the Si of 7, and 0.15 μm between the Si of 7 and the InP of 5); 10b is the surface patterning of the p-InP 3 (e.g., having a depth of 0.1 μm, a width of 725 nm, and a spacing of 725 nm (∧_{10b}=1450 nm)); 9, 10, 16, and 17 are set to Ti/Pt/Au (e.g., having thicknesses of 0.1 μm/0.05 μm/1 μm); 11 is set to SiN (e.g., having a refractive index of 1.9 and a thickness of 0.17 μm); 12 and 15 are set to Al (e.g., having a thickness of 0.2 μm); and 2 is set to SiO₂ (e.g., having a thickness of 0.95 μm, but having 0.15 μm between the InP of 3 and the Si of 14, and 0.4 μm between the Si of 14 and the Al of 15). Thereby, the semiconductor light receiving element (left) has the function described in reference to FIG. 7; and because the periodic structures of 13 and 14 are HCGs having the same period, the element on the right side functions as a semiconductor laser in which 4 is a laser active layer, and 13 and 14 are resonators. In the case of periods of ∧₁₃ and ∧₁₄ in the layer structures recited above, the laser oscillation wavelength is in the 1.3 μm band.

In the configuration described above, when applying a reverse bias to the light receiving element electrodes 8 and 9 (8 being negative and 9 being positive) and a forward bias to the semiconductor laser electrodes 16 and 17 (16 being positive and 17 being negative), in the light receiving element, a reverse bias electric field of the p-n junction is applied to the MQW; and the bandgap shifts to the longer wavelength side due to the QCSE described above. Also, in the semiconductor laser, a forward current of the p-n junction flows; carrier injection of electrons and holes into the MQW occurs; light emission of a wavelength corresponding to the unbiased bandgap occurs; and laser oscillation occurs when the bias current exceeds the threshold current.

Generally, a direct bandgap semiconductor has a light emission peak on the longer wavelength side of the bandgap because the direct bandgap semiconductor self-absorbs wavelengths shorter than the bandgap. Even in the case of a semiconductor laser, as a balance region where the absorption loss is low and the gain is large, there are many cases where laser oscillation occurs slightly on the longer wavelength side of the light emission spectrum peak. Therefore, generally, the light emission is on the longer wavelength side of the bandgap; and the light receiving efficiency of the light receiving element easily becomes low in the case where the light-emitting element and the light receiving element are made from the same semiconductor material.

In the embodiment of FIG. 8, because the light absorption layer 4 of the light receiving element is a MQW, bandgap shift occurs due to the QCSE due to the reverse bias electric field; and the light emission wavelength of the light-emitting element configured using the same MQW can receive light efficiently. In other words, for the configuration using the same MQW layer, it is possible for the output light of the semiconductor laser on the right side to be received efficiently by the light receiving element on the left side. Accordingly, the light-emitting element (an LED, a semiconductor laser, etc.) and the light receiving element can be collectively formed using one MQW layer, and can be used as an individual element or as an integrated element including a pair of an optical transmitting element and an optical receiving element. However, the light receiving efficiency is extremely low in a general MQW light receiving element. However, an extremely high light receiving efficiency can be obtained in the embodiment shown in FIG. 7.

Thus, according to the sixth embodiment (the modification) shown in FIG. 8, a light-emitting element and a light receiving element having the high cost performance of a high efficiency and a low cost or an integrated chip of a light-emitting element and a light receiving element are obtained by one device patterning.

### Seventh Embodiment

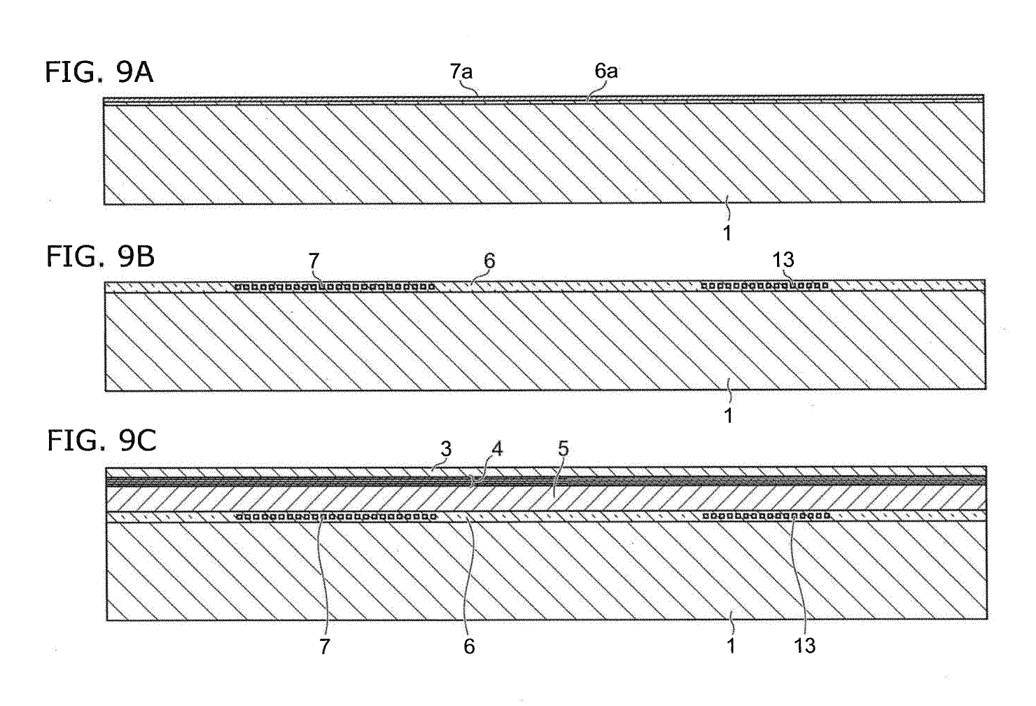

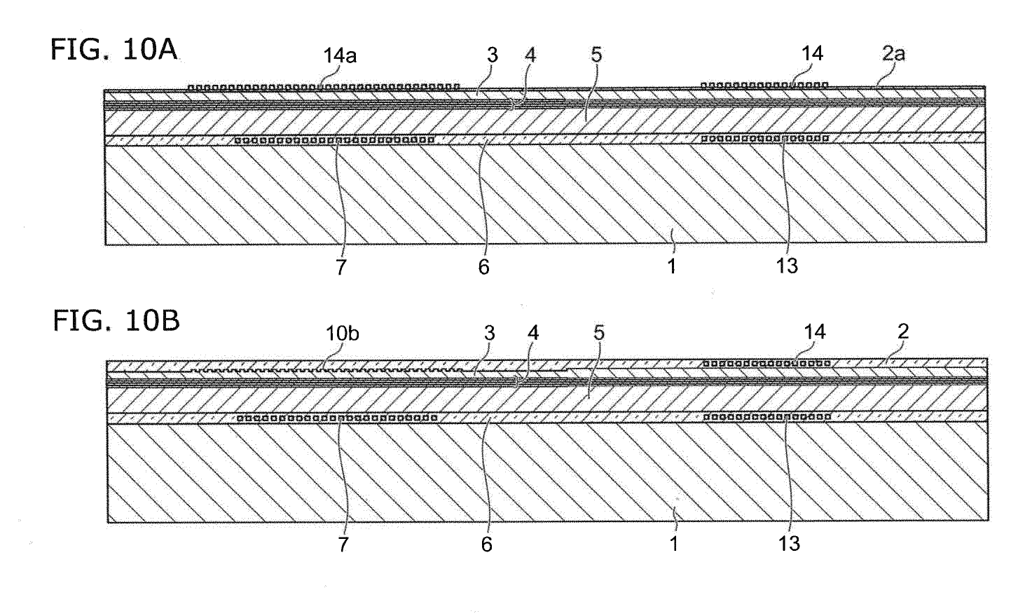

FIG. 9A to FIG. 9C, FIG. 10A, and FIG. 10B are schematic cross-sectional views showing manufacturing processes of a semiconductor light receiving element of a seventh embodiment. Here, an example of an integrated element is shown for a surface-input semiconductor light receiving element (left) in which the light is incident from below in FIG. 10B and a surface-type semiconductor laser (right) outputting light downward in FIG. 10B; and the manufacturing processes using the configuration example shown in FIG. 8 will now be described.

FIG. 9A is the state in which a low refractive index transparent material 6a and a high refractive index transparent material 7a are formed on the Si substrate 1; for example, 0.4 μm of SiO₂ is formed as 6a; and, for example, 0.4 μm of amorphous silicon is formed as 7a. A method such as CVD (Chemical Vapor Deposition), sputtering, etc., may be used as the formation methods.

FIG. 9B is the state in which the high refractive index transparent material 7a is patterned into an incidence diffraction grating and buried in the low refractive index transparent material 6; for example, 7a is patterned into the periodic structure 7 by photolithography; and SiO₂ is deposited by CVD as 6. At this time, the SiO₂ that is deposited by CVD has an unevenness corresponding to the periodic structure 7; and, for example, the surface is planarized by CMP (Chemical Mechanical Polishing).

FIG. 9C is the state in which the semiconductor multilayered films 3, 4, and 5 are formed on the low refractive index transparent material 6; for example, an InGaAs spacer of 0.2 μm, p-type InP of 0.3 μm, a MQW, and n-type InP of 0.8 are formed by crystal growth on an InP substrate by MO-CVD (Metal Organic Chemical Vapor Deposition), etc.; for example, 20 nm of SiO₂ is formed on the surface of the n-type InP; and this is bonded to the surface of the low refractive index transparent material 6. At this time, for example, to bond the n-type InP and the low refractive index transparent material 6, it is sufficient to use a method such as cleaning the surfaces by nitrogen sputtering in a vacuum and bonding the dean surfaces to each other; or performing oxygen plasma ashing and hydrophilizing treatment on the surfaces, bonding the processing surfaces to each other, and performing heating, pressurizing, etc. Subsequently, the InP substrate is removed by, for example, polishing and hydrochloric acid treatment; and the InGaAs spacer layer is removed using a sulfuric acid-based etchant.

FIG. 10A is the state in which a low refractive index transparent material 2a and a high refractive index transparent material are formed on the semiconductor layer 3, and the high refractive index transparent material is patterned into the horizontal diffraction gratings of 14 and 14a. For example, by using a method such as CVD, sputtering, etc., for example, 0.15 μm of SiO₂ is formed as 2a; for example, 0.4 μm of amorphous silicon is formed as 7a; and this is patterned into the periodic structures of 14 and 14a by photolithography.

FIG. 10B is the state in which 10b is formed by transferring the horizontal diffraction grating 14a of the light receiving element onto the semiconductor layer 3; and the entirety is buried in the low refractive index transparent material 2. It is sufficient to perform the process of transferring the horizontal diffraction grating 14a onto the semiconductor layer 3 by, for example, covering the right half of FIG. 10A with a photoresist, etc., and by patterning the surfaces of the low refractive index transparent material 2a and the semiconductor layer 3 by dry etching such as RIE (Reactive Ion Etching), etc., using 14a as a mask. Subsequently, it is sufficient to remove 14a and 2a of the left half of FIG. 10A and to form the low refractive index transparent material 2 similarly to FIG. 9B.

By such patterning, the light receiving element and the light-emitting element can be patterned by substantially the same processes; and a drastic process reduction is possible compared to a method in which the light receiving element and the light-emitting element are made separately. Accordingly, according to the method for manufacturing the semiconductor light receiving element of the seventh embodiment, it is possible to simultaneously form not only the light receiving element but also the light-emitting element; many optical elements can be simultaneously and collectively formed at any position in the wafer surface; it is easy to make an optical integrated element; and the yield is high because the number of processes is reduced drastically. In other words, the method is extremely promising as a method for manufacturing an optical integrated device, and can contribute to the realization of a highly functional large-scale optical integrated chip for high-speed optical information processing, etc.

The embodiments may include the following configurations.

### Configuration 1

A semiconductor light receiving element, comprising:

a first layer (e.g., a first periodic structure: the low refractive index transparent material of reference numeral 6 and the high refractive index transparent material of reference numeral 7);

a second layer (e.g., the light confinement layer of reference numeral 2), a direction from the first layer toward the second layer being aligned with a first direction;

a first semiconductor region (e.g., the semiconductor layer of reference numeral 3) provided between the first layer and the second layer;

a second semiconductor region (e.g., the semiconductor layer of reference numeral 5) provided between the first layer and the first semiconductor region; and

a third semiconductor region (e.g., the semiconductor layer of reference numeral 4) provided between the first semiconductor region and the second semiconductor region,

the first layer including

multiple first optical regions (e.g., the high refractive index transparent material of reference numeral 7), and

a second optical region (e.g., the low refractive index transparent material of reference numeral 6) provided between the multiple first optical regions,

at least a portion of the multiple first optical regions being arranged at a first period in a second direction crossing the first direction,

a refractive index of at least one of the multiple first optical regions being higher than a refractive index of the second optical region,

a first light being incident perpendicularly to the first layer along the first direction, and traveling at the first layer in multiple directions crossing the first direction,

a refractive index of the second layer being lower than a refractive index of the first semiconductor region, lower than a refractive index of the second semiconductor region, and lower than a refractive index of the third semiconductor region.

### Configuration 2

The semiconductor light receiving element according to Configuration 1, wherein a bandgap of the third semiconductor region is lower than a bandgap of the first semiconductor region and narrower than a bandgap of the second semiconductor region.

### Configuration 3

The semiconductor light receiving element according to Configuration 1 or 2, wherein

the third semiconductor region does not include an impurity, or

an impurity concentration included in the third semiconductor region is lower than an impurity concentration included in the first semiconductor region and lower than an impurity concentration included in the second semiconductor region.

### Configuration 4

The semiconductor light receiving element according to Configuration 1 or 2, wherein the third semiconductor region is non-doped.

According to the embodiments, a semiconductor light receiving element and a method for manufacturing the semiconductor light receiving element can be provided in which a decrease of the light receiving efficiency is suppressible.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed:

1. A semiconductor light receiving element, comprising at least:
a first periodic structure provided in a light incident portion, the first periodic structure splitting and converting, into non-perpendicular light in two or more directions, light incident from a direction perpendicular to the light incident portion;
a semiconductor multilayered film including a light absorption layer and being provided on the first periodic structure in contact with the first periodic structure; and
a light confinement layer provided on the semiconductor multilayered film, a refractive index of the light confinement layer being lower than a refractive index of the semiconductor multilayered film.

2. The element according to claim 1, further comprising a second periodic structure at a surface of the semiconductor multilayered film opposite to a surface contacting the first periodic structure, the second periodic structure direction-converting the non-perpendicular light into a horizontal direction.

3. The element according to claim 1, wherein the light absorption layer is disposed at a p-n junction portion and is sandwiched between a p-type semiconductor layer and an n-type semiconductor layer, an electrode being provided at each of the p-type semiconductor layer and the n-type semiconductor layer.

4. The element according to claim 1, wherein
the light absorption layer is sandwiched inside a low-concentration n-type semiconductor layer or a low-concentration p-type semiconductor layer, and
non-ohmic electrodes of two or more systems are provided in contact with the low-concentration n-type semiconductor layer or the low-concentration p-type semiconductor layer.

5. The element according to claim 1, wherein a difference between equivalent refractive indexes for horizontally-propagating light of a high refractive index portion and a low refractive index portion of the second periodic structure is less than 1.

6. The element according to claim 1, wherein a refractive index difference between a high refractive index material and a low refractive index material of the first periodic structure is 1 or more.

7. The element according to claim 1, wherein the first periodic structure is made of a two-dimensional periodic structure formed in a grating configuration in a light incident surface direction of the light incident portion.

8. The element according to claim 7, wherein the two-dimensional periodic structure is made of one of a triangular grating, a square grating, or a hexagonal grating.

9. The element according to claim 2, wherein the second periodic structure is made of a two-dimensional periodic structure matchable to a two-dimensional periodic structure of the first periodic structure.

10. The element according to claim 2, further comprising a third periodic structure on an outer side of the second periodic structure, the third periodic structure being a Bragg reflector for a light receiving wavelength.

11. The element according to claim 1, wherein a high refractive index material of the first periodic structure is one of monocrystalline silicon, polycrystalline silicon, or amorphous silicon.

12. The element according to claim 1, wherein the element is formed on a silicon substrate.

13. A method for manufacturing a semiconductor light receiving element, comprising at least:
forming a first low refractive index transparent film on a silicon substrate and forming a first silicon film on the first low refractive index transparent film;
forming a first periodic structure by patterning the first silicon film;
forming a second low refractive index transparent film on the first periodic structure and performing planarization or causing at least protrusion heights to be uniform for a surface of the second low refractive index transparent film;
forming a semiconductor multilayered film on the second low refractive index transparent film, the semiconductor multilayered film including a light absorption layer;
forming a second periodic structure by patterning a surface of the semiconductor multilayered film; and
forming a third low refractive index transparent film on the second periodic structure.

14. The method according to claim 13, wherein
the patterning of the semiconductor multilayered film surface includes at least:
forming a fourth low refractive index transparent film on the semiconductor multilayered film and forming a second silicon film on the fourth low refractive index transparent film;
forming a second periodic structure mask by patterning the second silicon film;
using the second periodic structure mask to pattern through the fourth low refractive index transparent film and partway through the semiconductor multilayered film; and
removing at least the second silicon film.
